(19) United States
(12) Patent Application Publication
(10) Pub. No.: US 2009/0102582 A1
(43) Pub. Date: Apr. 23, 2009

(54) RESONATOR DEVICE WITH SHORTED STUB AND MIM-CAPACITOR

(75) Inventors: Edwin Van Der Heijden, Eindhoven (NL); Marc G. M. Notten, Elsloo (NL); Hugo Veenstra, Kleine Brogel (BE)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: NXP B.V., Eindhoven (NL)

(21) Appl. No.: 12/300,372

(22) PCT Filed: May 9, 2007
(86) PCT No.: PCT/IB07/51751

§ 371 Date: Nov. 11, 2008

(30) Foreign Application Priority Data
May 11, 2006 (EP) 06113821.0

(51) Int. Cl. H01P 1/00; H04B 15/00; H01L 21/62

(52) U.S. Cl. 333/245; 333/12; 438/386; 257/E21.011

(57) ABSTRACT

At microwave frequencies, the use of transmission lines as a design element becomes interesting due to the small wavelengths. Inductors as part of an on-chip resonator can be made with a shorted stub, which is a transmission line, shorted at the end. Placing a MIM-capacitor at the beginning of the shorted stub can make a resonator. Shielding this kind of resonator by means of vias or stacked vias enables very compact filter designs.

The current invention is related to a resonator device with a shorted stub and a MIM-capacitor.

The current invention is also related to a method to manufacture such a resonator device.

The current invention is further related to the use of such a resonator device in an electronic device especially in filter application in the microwave frequency range.

Transmission line resonators for microwave applications especially in GHz frequency range are well known in the literature. Transmission lines always comprise a signal line and a ground line. Preferred embodiments of transmission lines at microwave frequencies are microstriplines with a signal line on a first side of a dielectric substrate and a ground line on the second of the dielectric substrate or coplanar waveguides with signal line and ground line other attached to the same side e.g. the first side of a dielectric substrate. In the latter embodiment an additional ground line can be attached to the second side of the dielectric substrate being electrically contacted to the ground line attached to the first side of the dielectric with the signal line forming a coplanar waveguide with ground.

In U.S. Pat. No. 6,825,734 a transmission line attached to or embedded in a dielectric substrate configured as a looped-stub resonator is disclosed, which can be used as a frequency selective element for an oscillator, such as a VCO of a phase locked loop. The length of the signal line of the transmission line has to be a fraction of the electrical wavelength at resonance frequency of the looped-stub resonator. The signal line can also be embedded to provide an inner resonant layer of an overall layered structure. The signal line is formed into a loop or multiple loops and may be terminated with a capacitor, short circuit, or open circuit. In the case the signal line is short-circuited to a ground line the fraction of the electrical wavelength is around a quarter of the electrical wavelength. This limitation with respect to the length of the signal line of the transmission line resonator results in large resonators.

It is an objective of the current invention to provide a resonator device with reduced size but comparable performance.

The objective is achieved by means of a resonator device with an input port comprising a dielectric substrate layer with a permittivity el, a transmission line comprising a signal line attached to the substrate layer and at least one electrically conductive ground structure also attached to the substrate layer, and the signal line is connected with the ground structure in an electrically conductive way, and a first electrically conductive contact of at least one capacitor with a capacitive density per area of the substrate layer greater than the capacitive density per area of the substrate layer of the signal line is connected to the signal line, and a second electrically conductive contact of the capacitor is connected to the ground structure. The signal line can be attached to a first surface of the substrate layer. In this case the electrically conductive ground structure is either attached to the first surface of the substrate in a way that a coplanar waveguide with or without ground plane is formed or the ground structure is attached to a second surface of the substrate layer. In the latter case the transmission line comprising the signal line and the ground structure is a microstripline or coplanar waveguide with ground plane. Alternatively the signal line can also be embedded between the dielectric substrate and a second dielectric substrate. The capacitor comprises two electrodes separated by means of an insulator or insulating layer.

The advantage of this invention in comparison to the prior art is that due to the higher capacitance density per substrate area of the capacitor in comparison to the capacitance density per substrate area of the signal line the length of the signal line can be less than a quarter of the wavelength of the resonance frequency of the resonator device. The capacitance density is defined by the capacitance between a conductive structure (e.g. the signal line) covering the substrate layer and the ground structure in relation to the area covered by the conductive structure on the substrate. The capacitor can be a discrete capacitor as e.g. a multilayer capacitor. Depending on the application as e.g. highly selective filters the capacitor has to be chosen in a way that the resonance frequency of the resonator do not strongly depend on the physical boundary conditions as e.g. temperature. The capacitor can also be integrated in the substrate layer simplifying the processing of the resonator device. The conductive layers and the dielectric layer or layers and the interconnections are preferably processed in a semiconductor process. In this case the resonator device comprises e.g. a silicon substrate but all other substrates as e.g. GaAs substrates and the like used in semiconductor processing can be used as well. If the substrate is conductive it can be used as ground structure electrically connected to ground. The electrical connection between the signal line and the ground structure is preferably placed at a first end of the signal line, and the capacitor is placed essentially at a second end of the signal line, and the input port electrically connected to the signal line is positioned at the second end of the signal line. The latter configuration enables to minimize the resonator device at a given resonance frequency by maximizing the capacitance and the inductance of the resonator device.

In a further embodiment of the current invention the capacitor is integrated in the substrate layer. The integration of the capacitor in the substrate would further reduce the size of the resonator device since no extra contact areas are needed in order to contact an external discrete capacitor by means of e.g. soldering. The integration of the capacitor in the substrate further reduces parasitic effects due to shorter electrical connections.

In another embodiment of the current invention the insulator or insulating layer of the capacitor is a high permittivity materials with a permittivity ∈₂ greater than the permittivity ∈₁ of the substrate layer. If the capacitor is integrated in the substrate layer materials as e.g. Ta₂O₅ and HfO₂ can be used, which can be integrated on Silicon. The capacitor can comprise a single layer configuration with only one dielectric layer between a bottom- and a top electrode (a plate capacitor), a multilayer configuration with at least two dielectric layers and the dielectric layers are separated by means of electrodes (stacked capacitor) or a coplanar interdigital (interdigitated) capacitor with comblike electrodes placed on high permittivity material. A combination of a coplanar interdigital capacitor with a plate or stacked capacitor is also possible.

In an alternative embodiment Barium Strontium Titanate (BST) or ferroelectrics as Lead Zirconate Titanate (PZT) can be used as insulator or insulating layer of the capacitor. BST and PZT can be integrated on Silicon by means of well-known thin film deposition technologies as sputtering and sol gel deposition. Advantages of using this materials and materials belonging to the same class of materials (Paraelectrics, Ferroelectrics) are the relatively high permittivity (e.g. PZT around 1000) and the permittivity can be tuned by means of an electric bias field enabling the control of the resonance frequency of the resonator device, which can be used for tuneable filters.

In another embodiment of the current invention the signal line and the ground structure are separated by means of the substrate layer. The transmission line comprising the signal line and the ground structure is in this case a microstripline. The signal line can also be embedded between the substrate layer and a second dielectric substrate. In this configuration there is preferably an electrically conductive layer being separated from the signal line by means of the second dielectric substrate and it's advantageous to connect the ground structure with the electrically conductive layer in an electrically conductive way e.g. by means of one or more vias. Vias enable the direct connection between the different layers comprising conductive structures and separated by means of insulating layers.

In a further embodiment of the current invention the signal line is circumvented by an electrically conductive shielding structure in the plane defined by the signal line and the shielding structure is electrically connected with the ground structure. The transmission line is in this embodiment a coplanar waveguide with a ground plane. The shielding structure can be used to separate the resonator device from other functional devices as e.g. a second resonator device in a filter configuration in order to minimize the interaction between the first resonator device and the second resonator device.

In one embodiment of the current invention vias or stacked vias are used in order to establish the electrically conductive connection between the shielding structure and the ground structure. The vias or stacked vias are preferably distributed around the signal line and in an advantageous configuration the distance between adjacent vias or stacked vias is less than halve of the wavelength of the resonance frequency of the resonator device taking into account the permittivity ∈₁ of the substrate. The small distance between the vias or stacked vias minimizes the coupling to other conductive structures or electrical devices that can be integrated on the substrate layer. By means of this measure several resonator devices can be integrated on one substrate with a small distance between the resonator devices for e.g. one or more filters with an excellent decoupling of the resonator devices improving the performance of the filter or filters and enabling a very compact filter design.

In one embodiment of the invention the substrate layer is a multilayer substrate. A multilayer substrate enables the integration of further functions on the different layers improving the integration density. In a special configuration the electrically conductive ground structure is a layer bounding the multilayer substrate that means only on one side of the ground structure is attached to a dielectric layer being part of the substrate layer. The ground structure is connected to ground, and the electrical contact between the signal line and the ground structure is at least one stacked via. Stacked vias are a combination of at least two vias stacked on top of each other in order to provide an electrically conductive connection of conductive structures separated by means of at least two insulating layers stacked on top of each other. In the case a shielding structure is provided, the electrical contact or contacts between this shielding structure with the ground structure is or are stacked vias shielding other functional parts integrated in the multilayer substrate. The capacitor is preferably integrated in the multilayer substrate and depending on the number of layers of the multilayer substrate several dielectric layers and electrode layers can be integrated forming a stacked capacitor with high capacitance density per area of the substrate layer even if the dielectric layers of the stacked capacitor comprise the same material as the substrate layer.

In one embodiment of the invention the capacitor is a Metal Insulator Metal (MIM)-capacitor. Especially the integration of high-Q MIM-capacitors enables the production of compact high-Q resonator devices suited for filter applications. Using metals as e.g. Copper, Aluminium, Aluminium Copper Alloys, Silver or Gold with a high electrical conductivity further reduces the losses of the resonator device.

It's further an objective of the current invention to provide a method of manufacturing a miniaturized resonator device.

The objective is achieved by means of a method comprising the steps of:

providing a semiconductor substrate;

providing an electrically conductive ground structure;

providing at least one substrate layer with a permittivity el;

providing at least one electrically conductive via through the at least one substrate layer to the ground structure;

integrating a capacitor in the at least one substrate layer;

connecting a second electrode of the capacitor with the ground structure in an electrically conductive way;

providing an electrically conductive layer on the substrate layer;

structuring the electrically conductive layer in a signal line and a shielding structure electrically connected to the signal line;

connecting the signal line and the shielding structure with the ground structure by means of the at least one via in an electrically conductive way. The semiconductor substrate can be a conductive substrate or parts of the substrate can be made conductive by means of doping. If the semiconductor substrate or parts of the semiconductor substrate are conductive they can be used to provide the conductive ground structure. In the case the semiconductor substrate is not electrically conductive or an electrical insulation between the semiconductor substrate and further electrically conductive structures is wanted a first conductive layer comprising the ground structure can be deposited on the non-conductive semiconductor substrate or on top of an intermediate insulating layer made of e.g. silicon oxide or silicon nitride. Depending on the further processing conditions (e.g. materials, temperature etc.) Copper, Silver, Platinum, oxidic conductors can be used. The first conductive layer can be patterned by e.g. lithographic methods. On top of the conductive ground structure at least one dielectric layer with a permittivity ∈₁ is deposited and patterned forming the substrate layer. The dielectric material can be silicon oxide, silicon nitride or the like.

If only one dielectric layer is deposited the substrate layer comprises only this single layer, an insulating material with a permittivity ∈₂ bigger than the permittivity of the substrate layer comprised by the capacitor is deposited on a place where the dielectric layer has been removed on top of the electrically conductive ground structure. The ground structure comprises in this case the second electrode of the capacitor.

If more than one dielectric layer is deposited the substrate layer comprises all dielectric layers. In a subsequent order a dielectric layer is deposited and patterned followed by the deposition and patterning of an electrically conductive layer comprising parts of further functional devices and the vias finally connecting the structured electrically conductive layer comprising the signal line and the shielding structure with the ground structure. The deposition and patterning of the insulating material comprised by the capacitor can be implemented in the subsequent processing of the dielectric layer and the electrically conductive layer as in the case of only one dielectric layer. In the case the number of patterned insulating layers with a permittivity ∈₂ comprised by the capacitor is less than the number of dielectric layer forming the substrate layer at least one electrode comprised by the capacitor is at least part of an electrically conductive layer is embedded between two dielectric layers being part of the substrate layer. In this case at least one electrode comprised by the capacitor is contacted with the signal line or the ground structure by means of a via or a stacked via. Finally a conductive layer is deposited and patterned on top of the substrate layer. This patterned electrically conductive layer comprises the signal line and the shielding structure. A part of the signal line can comprise the first electrode of the capacitor or the signal line is electrically connected to the first electrode by means of a via or stacked via.

The current invention can be used as part of a filter where at least two resonators are comprised. Especially the combination of the resonant structure with the integrated capacitor together with the vias or stacked vias results in a very compact design of the filter. An integration of additional capacitors in the substrate layer not comprised by the resonator or resonators enables more sophisticated filters. The invention can be applied in microwave applications beyond 10 GHz and is not limited to single-ended use only. By using two filters, the filter can be made differential. This can be used for instance in satellite TV receivers, automotive collision avoidance radars at 24 GHz or 60 GHz WLAN/WPAN.

The present invention will now be explained in greater detail with reference to the figures, in which similar parts are indicated by the same reference signs, and in which:

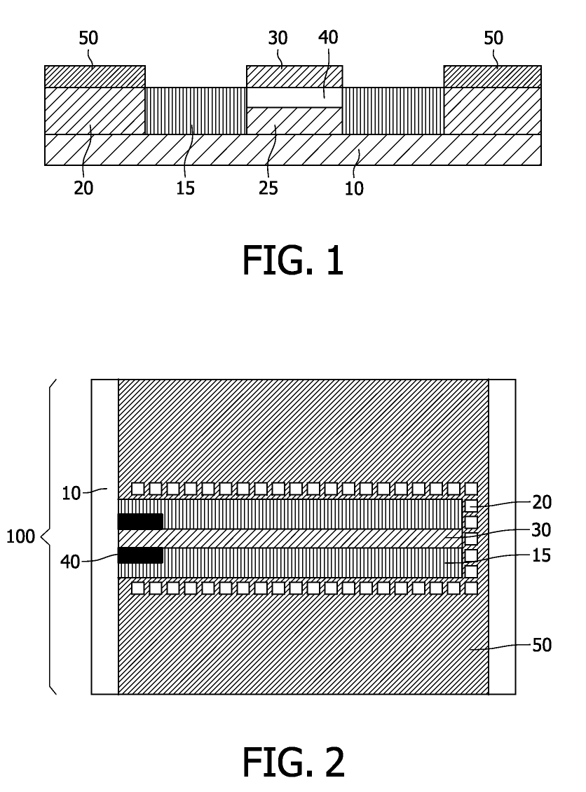

FIG. 1 shows a cross section of one embodiment of the current invention.

FIG. 2 shows a principal sketch of a layout of a resonator device according to the current invention.

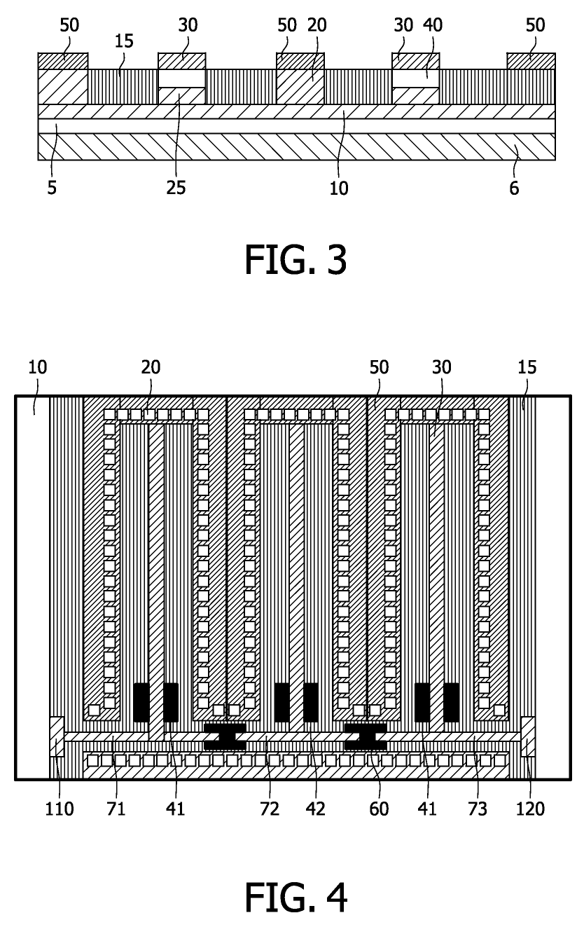

FIG. 3 shows a cross section of a combination of two resonator devices according to the current invention.

FIG. 4 shows a principal sketch of the implementation of a resonator device according to the current invention in the layout of a 3^{rd}-order band-pass filter.

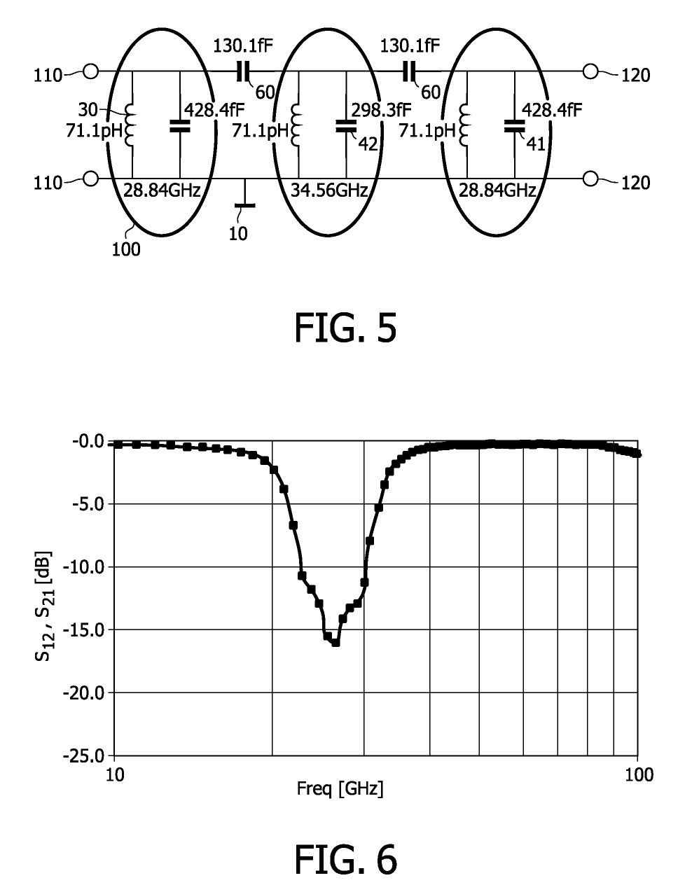

FIG. 5 shows the schematic of the 3^{rd}-order band-pass filter shown in FIG. 4.

FIG. 6 depicts the measured reflection of the 3^{rd}-order band-pass filter shown in FIG. 4.

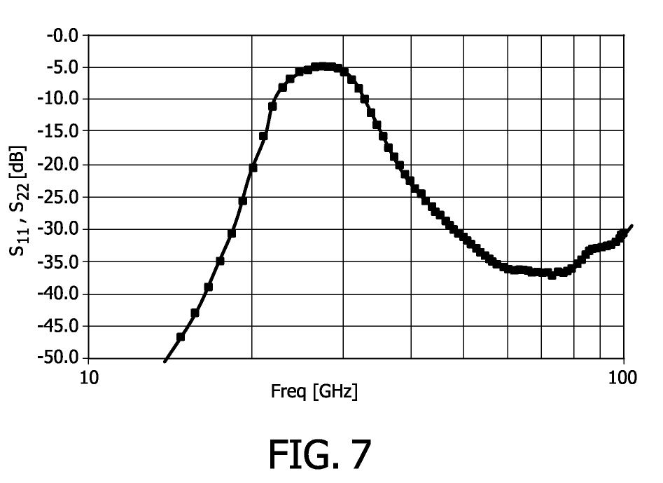

FIG. 7 depicts the measured transmission of the 3^{rd}-order band-pass filter shown in FIG. 4.

In FIG. 1 a cross section of the region of a resonator device where the MIM-capacitor is implemented is shown. The electrically conductive metallization forming the shielding structure 50 is connected to the ground metallization forming the ground structure 10 by means of stacked vias 20. The ground metallization can be a conductive semiconductor substrate as e.g. doped silicon. A substrate layer 15 made of e.g. SiO₂ with a permittivity of around 4 circumvents the stacked vias. The signal line 30 is connected to a first electrode of an integrated MIM-capacitor 40 comprising a patterned dielectric layer as e.g. HfO₂ with a permittivity of around 20 greater than the permittivity of the substrate layer 15. The second electrode of the MIM-capacitor is connected to the ground metallization by means of a stacked via 25.

FIG. 2 shows a principal sketch of a layout (top view) of a resonator device 100 according to the current invention. The ground metallization forming the ground structure 10 is either a conductive semiconductor substrate or a conductive layer deposited on top of an insulating layer as e.g. SiO₂ on a silicon substrate. The substrate layer 15 comprises one or more dielectric layer or layers with a permittivity el deposited on top of the ground structure 10. The electrically conductive metallization forming the shielding structure 50 as well as the signal line 30 is deposited on top of the substrate layer 15. The stacked vias 20 connect the shielding structure 50 with the ground structure 10 around the signal line 30 and the signal line 30 is electrically connected with the short circuited shielding structure 50 at the right side of the resonator device 100 forming a shorted stub together with the ground structure 10. The left side of the signal line 30 extends above a dielectric material with a permittivity ∈₂ forming a first electrode of a MIM-capacitor 40. The second electrode of the MIM-capacitor (not shown) is connected to the ground metallization 10.

In FIG. 3 a cross section of the combination of two resonator devices as shown in FIG. 1 is depicted. The stacked vias 20 between the resonators shield the resonators minimizing interference enabling a compact filter design. In contrast to FIG. 1 the ground metallization is deposited on an intermediate or insulating layer 5 which can be a silicon oxide or silicon nitride layer deposited on a silicon substrate 6.

FIG. 4 shows the layout (top view) of the implementation of three resonator devices 100 in a 3^{rd}-order band-pass filter. The band-pass filter comprises two resonators comprising a MIM-capacitor 41 and one resonator comprising a MIM-capacitor 42. The signal lines 30 of the three resonator devices 100 are placed parallel to each other connected at one side to the shielding structure 50. The signal lines are separated from each other by means of the shielding structure 50. At the other end of the signal lines 30 where the MIM-capacitors 41, 42 are integrated the signal lines 30 are connected with 50 Ohm transmission lines 71, 72, 73 forming T like structures. A first contact port 110 is connected by means of the 50 Ohm transmission line 71 to a first resonator with a MIM-capacitor 41, the transmission line 71 further extends to and ends upon a first series capacitor 60 forming a first electrode of the first series capacitor 60, a second 50 Ohm transmission line 72 starts upon the first series capacitor 60 forming a second electrode of the first series capacitor 60 and contacts the signal line 30 of a second resonator device with a MIM-capacitor 42 and further extends to and ends upon a second series capacitor 60 forming a first electrode of the second series capacitor 60. A third 50 Ohm transmission line 73 extends from the second series capacitor 60 forming a second electrode of the second series capacitor 60, connects the signal line 30 of the third resonator device with a MIM-capacitor 41 and further extends to a second contact port 120. The series capacitors 60 comprise parts of the 50 Ohm transmission lines 71, 72, 73 building the contact electrodes, insulating material with the permittivity ∈₂ and parts of the second conductive structure.

FIG. 5 shows a schematic of the band-pass filter depicted in FIG. 4. The band-pass filter is depicted as a two port with the ports 110 and 120. The resonator devices 100 are depicted as LC parallel circuits with the capacitors C comprising the MIM-capacitors 41 and 42. The LC parallel circuits are at one side connected to ground via the ground structure 10 and at the other side connected to the series capacitors 60 and the ports 110 and 120 as described above.

FIG. 6 and FIG. 7 shows the measured S₁₁, S₂₂, S₁₂ and S₂₁ scattering parameters of a band-pass filter manufactured according to the layout shown in FIG. 4 and the schematic shown in FIG. 5. The reflection S₁₂, S₂₁ depicted in FIG. 6 show the expected low values in the pass-band (around 24 GHz used for e.g. car radar) and the transmissions S₁₁, S₂₂ shown in FIG. 7 show the expected high values in the pass-band indicating the high-Q resonators.

The present invention will be described with respect to particular embodiments and with reference to certain drawings but the invention is not limited thereto but only by the claims. Any reference signs in the claims shall not be construed as limiting the scope. The drawings described are only schematic and are non-limiting. In the drawings, the size of some of the elements may be exaggerated and not drawn on scale for illustrative purposes. Where the term “comprising” is used in the present description and claims, it does not exclude other elements or steps. Where an indefinite or definite article is used when referring to a singular noun e.g. “a” or “an”, “the”, this includes a plural of that noun unless something else is specifically stated.

Furthermore, the terms first, second, third and the like in the description and in the claims, are used for distinguishing between similar elements and not necessarily for describing a sequential or chronological order. It is to be understood that the terms so used are interchangeable under appropriate circumstances and that the embodiments of the invention described herein are capable of operation in other sequences than described or illustrated herein.

Moreover, the terms top, bottom, first, second and the like in the description and the claims are used for descriptive purposes and not necessarily for describing relative positions. It is to be understood that the terms so used are interchangeable under appropriate circumstances and that the embodiments of the invention described herein are capable of operation in other orientations than described or illustrated herein.

1. A resonator device with an input port comprising a dielectric substrate layer with a permittivity ∈₁, a transmission line comprising a signal line attached to the substrate layer and at least one electrically conductive ground structure also attached to the substrate layer, and the signal line is connected with the ground structure in an electrically conductive way, and a first electrically conductive contact of at least one capacitor with a capacitive density per area of the substrate layer greater than the capacitive density per area of the substrate layer of the signal line is connected to the signal line, and a second electrically conductive contact of the capacitor connected to the ground structure.

2. A resonator device according to claim 1, characterized in that the at least one capacitor is integrated in the substrate layer.

3. A resonator device according to claim 1, characterized in that the capacitor comprises an insulator having a permittivity ∈₂ greater than the permittivity ∈₁ of the substrate layer.

4. A resonator device according to claim 1, characterized in that the permittivity of the insulator in the at least one capacitor can be tuned by electromagnetic fields.

5. A resonator device according to claim 1, characterized in that the signal line and the ground structure are separated the substrate layer.

6. A resonator device according to claim 5, characterized in that the signal line is circumvented by an electrically conductive shielding structure in the plane defined by the signal line and the shielding structure is electrically connected with the ground structure.

7. A resonator device according to claim 6, characterized in that the shielding structure is connected to the ground structure by vias or stacked vias in an electrically conductive way shielding the signal line.

8. A resonator device according to claim 1, characterized in that the substrate layer is a multilayer substrate.

9. A resonator device according to claim 1, characterized in that the capacitor is a Metal Insulator Metal (MIM)-capacitor.

10. Method of manufacturing a resonator device, comprising the steps of:
providing a semiconductor substrate;
providing an electrically conductive ground structure;
providing at least one substrate layer with a permittivity ∈₁;
providing at least one electrically conductive via through the at least one substrate layer to the ground structure;
integrating a capacitor in the at least one substrate layer;
connecting a second electrode of the capacitor with the ground structure in an electrically conductive way;
providing an electrically conductive layer on the substrate layer;
structuring the electrically conductive layer in a signal line and a shielding structure electrically connected to the signal line;
connecting the signal line and the shielding structure with the ground structure by the at least one via in an electrically conductive way.
